(19) United States
(12) Patent Application Publication
(10) Pub. No.: US 2009/0142912 A1
(43) Pub. Date: Jun. 4, 2009

(54) Method of Manufacturing Thin Film Semiconductor Device and Thin Film Semiconductor Device

(75) Inventor: Masafumi Kunii, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION, Tokyo (JP)

(21) Appl. No.: 12/327,939

(22) Filed: Dec. 4, 2008

Related U.S. Application Data
(62) Division of application No. 11/196,109, filed on Aug. 3, 2005, now abandoned.

(30) Foreign Application Priority Data
Aug. 4, 2004 (JP) JP 2004 227470

(51) Int. Cl. H01L 21/3205

(52) U.S. Cl. 438/591; 257/E21.294

(57) ABSTRACT

A method of manufacturing a thin film semiconductor device that includes forming a thin film transistor on a substrate, forming a layer insulation film on the substrate, the layer insulation film containing no hydroxyl group in at least a film constituting a lowermost layer in the state of covering said thin film transistor and linking oxygen or hydrogen to dangling bonds in the semiconductor thin film constituting the thin film transistor by a heat treatment in a moisture atmosphere after the formation of the layer insulation film.

### CROSS-REFERENCE TO RELATED APPLICATIONS

This application is a divisional application of U.S. patent application Ser. No. 11/196,109, entitled “Method of Manufacturing Thin Film Semiconductor Device and Thin Film Semiconductor Device,” filed on Aug. 3, 2005 the entirety of which is herein incorporated by reference. This present invention claims priority to Japanese Patent Application No. 2004-227470 filed on Aug. 4, 2004, the entirety of which is also incorporated by reference herein to the extent permitted by the law.

### BACKGROUND OF THE INVENTION

The present invention relates to a method of manufacturing a thin film semiconductor device and a thin film semiconductor device, and particularly to a method of manufacturing a thin film semiconductor device and a thin film semiconductor device which are suitable for manufacturing a display drive panel in a flat panel display.

A flat panel display of a liquid crystal display, an organic EL display or the like is provided with thin film transistors (TFTs) as drive elements for pixel electrodes. Among these components, the poly-Si-TFT using polycrystalline silicon (poly-Si) as a semiconductor thin film is paid attention to on the ground that it can form a drive circuit, it enables incorporation of a high-function circuit in a panel and, hence, it enables conversion into the so-called system-on-glass structure. Meanwhile, in order to realize the formation of poly-Si.TFTs not on a quartz substrate but on an inexpensive glass substrate, the so-called low-temperature poly-Si process in which the manufacturing process temperature is suppressed to 600° C. or below has been developed.

In the manufacture of poly-Si-TFTs by the low-temperature poly-Si process, there has been used a method in which a film of amorphous silicon (a-Si) is formed as a semiconductor thin film on a glass or other insulating substrate by a plasma CVD process and the film is polycrystallized by treating it through irradiation with an intense beam of excimer laser or the like (laser anneal). It is well known, however, that the poly-Si obtained in this manner contains a multiplicity of defective levels arising from the uncoupled bonds (dangling bonds) of silicon at grain boundaries or in crystal grains, and, due to the electric charges trapped in the defective levels, a grain boundary potential barrier is formed against the carriers, such as electrons and holes, running through the inside of crystals. Where the potential barrier is high, the carrier mobility is lowered, resulting in that high-performance TFTs cannot be formed.

In order to prevent such a deterioration of the performance of TFT, there has been well known the so-called hydrogenation anneal in which the dangling bonds are terminated by bonding hydrogen or the like thereto so as to reduce the defective levels. As the hydrogenation anneal, there have been known a method in which a silicon oxide film, a silicon nitride film or the like is built up on the polycrystalline silicon film and thermal annealing is conducted to diffuse the hydrogen present in the silicon oxide or silicon nitride film into the polycrystalline silicon, and a method in which the substrate is exposed to a hydrogen plasma to achieve hydrogeneration. However, of the hydrogen introduced into the film by such a method, the hydrogen atoms contributing to termination of the dangling bonds are very few, and most of the dangling bonds are left unterminated. Besides, the Si—H bond energy is about 3.0 eV, and the hydrogen bonds would be lost upon the thermal anneal at 400 to 500° C.

In view of this, there has been proposed a process of conducting a heat treatment in a moisture atmosphere (water vapor anneal) to bond oxygen to the dangling bonds and thereby to lower the defective levels. The bond energy of Si—O bond is about 4.7 eV, which is higher than that of Si—H bond, so that the Si—O bond is stable against processes and hot carriers at a higher temperature. Particularly, since the water vapor anneal permits a batch process, it is more suited to mass production as compared with the oxygen plasma process, and it promises a higher oxidation rate as compared with the oxygen anneal process.

The manufacture of TFTs by application of the water vapor anneal is conducted as follows. First, a silicon oxide film is formed in the state of covering a polycrystallized semiconductor thin film. Next, water vapor anneal is conducted to bond oxygen to the dangling bonds in the semiconductor thin film constituting the TFTs, thereby terminating the dangling bonds. Thereafter, the silicon oxide film and the semiconductor thin film are patterned to achieve device isolation, then a gate insulation film is formed in the state of covering the patterns, and gate electrodes are formed. In the TFTs formed following such a manufacturing procedure, the silicon oxide film having been subjected to the water vapor anneal is also used as part of the gate insulation film (see Japanese Patent Laid-open No. 2002-151526); and Japanese Patent Laid-open No. 2002-208707).

Further, the silicon oxide film formed by a low-temperature process is low in film denseness, and the atoms constituting the film are liable to be present in the state of having dangling bonds, which may serve as electric charges in the film in some cases. In addition, in the silicon oxide film, silicon nitride film and the like, unreacted Si is left in the film, to serve as fixed electric charges in some cases. Further, damages arising from electrostatic discharge breaking out during or after the formation of the device are liable to be present in the film, and the damages are also liable to remain as fixed electric charges in the insulation film. When the fixed electric charges are left in the gate insulation film or layer insulation film in TFT, they cause a shift of the threshold voltage (Vth) of the TFT, leading to an increase in the leak current of the TFT; this will appear as defects of phosphor in the case of pixel TFTs, and as defects in circuit operation in the case of TFTs for peripheral drive circuits. In the worst case, dielectric breakdown occurs due to electrostatic discharge, leading to defects in insulation between input terminals, for example. In the cases of liquid crystal display, organic EL display and the like, devices are formed on a glass substrate which is an insulator and, therefore, are more liable to be electrostatically charged, as compared with semiconductor devices formed on an Si wafer; in addition, the devices on glass substrate are weak in electrostatic endurance of insulation film, so that electrostatically caused defects are frequently generated in the devices.

In order to obviate the above-mentioned problems, there has been proposed a method in which, after formation of a silicon oxide film on a semiconductor thin film, water vapor annealing is conducted in a pressurized atmosphere so as to contrive a higher denseness, like in the plasma CVD process (see Japanese Patent Laid-open No. 2003-188182).

However, the thin film transistor formed by applying the production method using the water vapor anneal as above mentioned has the following problem. The carrier mobility in the semiconductor thin film is secured, but, particularly in the case of n-channel TFT, the threshold voltage (Vth) would be abnormally shifted in the minus direction.

In addition, even in the case of conducting water vapor anneal with the same timing as that in the conventional hydrogeneration anneal, an abnormal shift of the threshold voltage (Vth) is generated. Specifically, an abnormal shift of threshold voltage (Vth) in the minus direction is generated in the n-channel TFT in the same manner as above, even in the case where, as shown in FIG. 10, a TFT 102 is formed on a substrate 101, then a layer insulation film 105 composed of a silicon oxide film 103 and a silicon nitride film 104 thereon is formed, and a water vapor anneal is conducted in a moisture atmosphere H.

FIG. 11A shows a Vgs (gate voltage)-Ids (drain current) curve of TFT in the case where the water vapor anneal is conducted following such a procedure. FIG. 11B shows a Vgs-Ids curve in an n-channel TFT which functions normally, by way of comparison. By comparing these figures, it can be confirmed that the threshold voltage (Vth) is abnormally shifted in the n-channel TFT having been subjected to the water vapor anneal following the above-mentioned procedure.

Further, in the manufacture of a thin film semiconductor device by a low-temperature process, it may be necessary for the layer insulation film covering the thin film transistor to be formed at a low temperature; however, as has been described above, a layer insulation film formed by a low-temperature process is low in film denseness. Therefore, as above-mentioned, fixed electric charges would remain in the layer insulation film to cause various defects, leading to a lowering in the reliability of the thin film semiconductor device.

Thus, there is a need for providing a method of manufacturing a thin film semiconductor device and a thin film semiconductor device which includes thin film transistors capable of securing the TFT threshold voltage irrespectively of conduction type and which is high in reliability.

### SUMMARY OF THE INVENTION

In order to fulfill the above need, according to an embodiment of the present invention, there is provided a method of manufacturing a thin film transistor which includes the following steps. First, in a first step, a thin film transistor is formed on a substrate. Next, in a second step, a layer insulation film containing no hydroxyl group (—OH group) in at least a film constituting a lowermost layer is formed on the substrate in the state of covering the thin film transistor. Thereafter, in a third step, a heat treatment is conducted in a moisture atmosphere to link oxygen to dangling bonds present in a semiconductor thin film constituting the thin film transistor.

According to the manufacturing method as above, the layer insulation film containing no —OH group in the lowermost layer film is formed in the state of covering the thin film transistor (TFT). Therefore, in the subsequent heat treatment in the moisture atmosphere (water vapor anneal), oxygen is linked to the dangling bonds in the semiconductor thin film constituting the thin film transistor to thereby terminate the dangling bonds with oxygen or hydrogen, without inducing any influence of the —OH groups in the layer insulation film on the thin film transistor. Moreover, the layer insulation film is also subjected to the water vapor anneal, so that an enhancement of the denseness of the layer insulation film is contrived.

Here, FIG. 1 shows the relationship between Si—OH bond concentration in a TFT-covering insulation film (silicon oxide film) and the threshold voltage (Vth) of the n-channel TFT, after the water vapor anneal. FIG. 2 shows the results of measurement of n-channel TFT transfer characteristic (gate voltage-drain current characteristic) on the basis of each Si—OH bond concentration in the gate insulation film (silicon oxide film). Incidentally, the Si—OH bond concentration was measured by applying the Fourier-transform infrared spectroscopy to samples obtained by applying the water vapor anneal to a silicon oxide film formed on an Si wafer simultaneously with and in the same chamber as the thin film transistor manufacturing process.

As is clear from FIG. 1, the Si—OH bond concentration and the Vth of n-channel TFT are in a substantially linear relationship. Namely, it was confirmed that the Vth is more shifted in the minus direction as the Si—OH bond concentration is higher. This is clearly seen also from FIG. 2.

Therefore, it is seen that a thin film transistor free of the Vth shift to the minus side even in the n-channel can be obtained, also in the case where the layer insulation film containing no —OH group in at least the lowermost layer film is formed in the state of covering the thin film transistor (TFT) and thereafter the water vapor anneal for terminating the dangling bonds with oxygen (partly hydrogen) stably and securely is conducted, as in the manufacturing method according to an embodiment of the present invention.

Incidentally, the Vth shift dependent on the Si—OH bond concentration as described referring to FIGS. 1 and 2 above is not observed in the case of a p-channel thin film transistor. Therefore, the phenomenon of the Vth shift in the n-channel TFT cannot be explained using a model of influence of the water vapor anneal on fixed electric charges in the film.

The reason why the large minus shift of Vth is observed only for the n-channel TFT device is considered as follows. As for the behavior of hydrogen atoms in silicon, it has been reported, as for example shown in Physical Review B, Volume 41, (1990), p. 12354 and the like, that a P-H derivative is dissociated under the crystal field in silicon in the manner of P-H→P⁺ H⁻ (1), to generate stable H⁻ ions, which are moved in silicon due to the presence of an electric field. On the other hand, the Si—OH bond present solely cannot find the mate with which the hydrogen atom is to be coupled, and an annealing at a high temperature of 1000° C. or above is needed for complete dissociation of hydrogen from the OH bonds; in the n-channel thin film transistor, however, P atoms are present in the source/drain regions as the mate with which H is to be coupled, so that a P-H derivative is easily produced. It is considered that, once the P-H bonds are formed, H⁻ ions are generated in silicon according to the formula (1), and the H⁻ ions are moved into the channel under the drain field of the thin film transistor, so that negative charges are accumulated in the channel, resulting in the Vth shift in the minus direction. On the other hand, the impurity atoms contained in the source/drain regions in the p-channel thin film transistor are atoms of boron (B), and no Group V element (e.g., P) that is stably coupled with H is present (or little, if present), so that there is little influence on the Vth shift.

In addition, according to another embodiment of the present invention, there is provided a first thin film semiconductor device including a thin film transistor containing a Group V element in a source region and a drain region of a semiconductor thin film containing silicon as a main constituent, and a layer insulation film provided on a substrate in the state of covering the thin film transistor, wherein at least the lowermost layer of the layer insulation film includes a silicon nitride film.

In the first thin film semiconductor device as above, at least the lowermost layer of the layer insulation film covering the thin film transistor includes the silicon nitride film, whereby it is ensured that the lowermost layer of the layer insulation film contains few —OH groups, and a thin film transistor with little Vth shift as above-mentioned is obtained.

According to a further embodiment of the present invention, there is provided a second thin film semiconductor device including a thin film transistor containing a Group V element in a source region and a drain region of a semiconductor thin film containing silicon as a main constituent, and a layer insulation film provided on a substrate in the state of covering the thin film transistor, wherein the layer insulation film has been made denser by a heat treatment in a moisture atmosphere.

As has been described above, according to the method of manufacturing a thin film semiconductor device according to an embodiment of the present invention, a thin film transistor with a stable Vth irrespective of conduction type can be obtained, without abnormal shift of Vth of the n-channel thin film transistor, even in the case where a heat treatment in a moisture atmosphere is conducted. Moreover, it is possible to contrive an enhancement of the denseness of the layer insulation film covering the thin film transistor. Therefore, it is possible to enhance the electrostatic endurance of the layer insulation film and to prevent electrostatically caused defects from being generated. As a result, it is possible to contrive an enhancement of the reliability of the thin film semiconductor device.

In addition, according to the first thin film semiconductor device according to another embodiment of the present invention, at least the lowermost layer of the layer insulation film covering the thin film transistor includes a silicon nitride film, whereby it is possible to stabilize the threshold (Vth) of the n-channel TFT and to contrive a higher reliability.

Further, according to the second thin film semiconductor device according to a further embodiment of the present invention, the layer insulation film covering the thin film transistor has been made denser by a heat treatment in a moisture atmosphere, whereby it is possible to prevent defects or troubles from being generated by the influence of fixed electric charges in the layer insulation film and to contrive a higher reliability.

### BRIEF DESCRIPTION OF THE DRAWINGS

FIG. 1 is a graph showing the relationship between Si—OH bond concentration in a silicon oxide film and threshold (Vth) of an n-channel TFT;

FIG. 2 is a graph showing the transfer characteristic (gate voltage-drain current characteristic) of an n-channel TFT on the basis of each Si—OH bond concentration in a silicon oxide film;

FIG. 3 is a configuration diagram showing one example of a treating apparatus used in the manufacturing method according to the present invention;

FIGS. 4A to 4E are sectional step views (No. 1) illustrating the manufacturing method according to a first embodiment;

FIGS. 4F to 4H are sectional step views (No. 2) illustrating the manufacturing method according to the first embodiment;

FIGS. 4I to 4L are sectional step views (No. 3) illustrating the manufacturing method according to the first embodiment;

FIGS. 5A to 5C are sectional step views illustrating the manufacturing method according to a second embodiment;

FIGS. 6A to 6C are sectional step views illustrating the manufacturing method according to a third embodiment;

FIGS. 7A to 7E are sectional step views (No. 1) illustrating the manufacturing method according to a fourth embodiment;

FIGS. 7F to 7I are sectional step views (No. 2) illustrating the manufacturing method according to the fourth embodiment;

FIG. 7J is a sectional step view (No. 3) illustrating the manufacturing method according to the fourth embodiment;

FIG. 8A is a graph showing the transfer characteristic (gate voltage-drain current characteristic) of an nTFT according to the third embodiment, and FIG. 8B is a graph showing a comparison;

FIG. 9A is a graph showing the transfer characteristic (gate voltage-drain current characteristic) of a pTFT according to the third embodiment, and FIG. 9B is a graph showing a comparison;

FIG. 10 is a sectional diagram illustrating one example of a manufacturing method according to the related art; and

FIGS. 11A and 11B are graphs for illustrating the problems involved in the manufacturing method according to the related art.

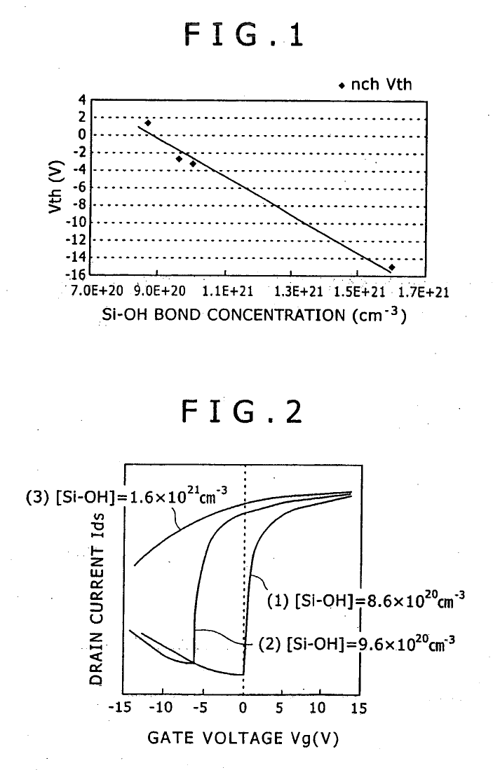

### DETAILED DESCRIPTION OF THE PRESENTLY PREFERRED EMBODIMENTS

Now, some embodiments of the present invention will be described in detail below, based on the drawings. Incidentally, here, before description of the embodiments of the manufacturing method, the configuration of a treating apparatus used in the embodiments will be described, and then first to fourth embodiments will be described.

### Treating Apparatus

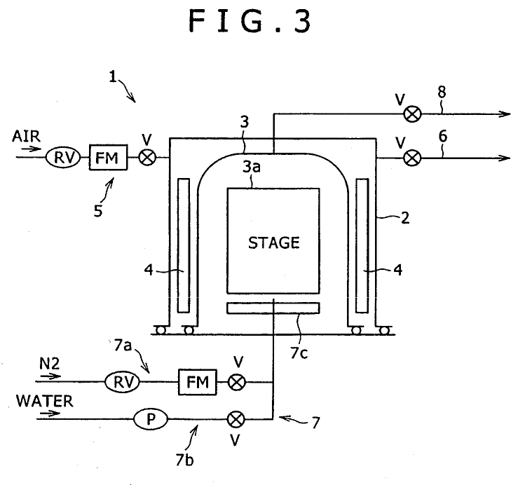

FIG. 3 is a configuration diagram of one example of the treating apparatus used in the following embodiments. The treating apparatus 1 shown in the figure includes a pressure vessel 2 sealed gas-tight, a treating chamber 3 sealed gas-tight in the inside of the pressure vessel 2, a heater 4 for heating the treating chamber 3, a pressure rise line 5 and a pressure reduction line 6 connected to the pressure vessel 2, and a gas supply line 7 and an exhaust line 8 connected to the treating chamber 3.

The treating chamber 3 is a quartz pipe whose inside surface is formed of quartz, and is so configured as to prevent metals from mixing in. In the treating chamber 3, a stage 3a on which a plurality of substrates to be treated (not shown) such as glass substrates and silicon substrates can be mounted is disposed so that the substrates to be treated can be treated in a batch treatment mode.

The heater 4 is provided so as to surround the periphery of the treating chamber 3, and is so configured that the inside of the treating chamber 3 can be maintained at a temperature of 300 to 700° C.

The pressure rise line 5 is connected to an air supply source, has a pressure reducing valve RV, a flowmeter FM, and a valve V, and is so designed as to introduce air into the pressure vessel 2 by opening and closing the valve V. On the other hand, the pressure reduction line 6 has a pressure reducing valve V, and can reduce the pressure inside the pressure valve 2 by exhausting.

At an upstream portion in the case of referring to the treating chamber 3 side as the downstream side, the gas supply line 7 is branched into an inert gas supply line 7a for supplying nitrogen gas (N₂) or the like, a water supply line 7b, and a treating gas supply line for supplying a treating gas (oxygen or dinitrogen monoxide or the like) (not shown). In addition, the gas supply line 7 is provided, at a downstream portion for discharging the treating gas into the treating chamber 3, with a heater 7c for heating the treating gas to a temperature equivalent to the temperature inside the treating chamber 3.

The inert gas supply line 7a has a supply source of the inert gas such as nitrogen (N₂), a pressure reducing valve RV, a flowmeter FM, and a valve V, and is so configured that the inert gas can be supplied into the treating chamber 3 by opening and closing the valve V, to provide a predetermined treating gas atmosphere in the treating chamber 3, and the pressure inside the treating chamber 3 can be raised to a value of 0.1 to 5 MPa. The water supply line 7b has a pump P and a valve V, and is so configured as to pump up water from a water source, to supply the water to the heater 7c by opening and closing the valve V, to evaporate the water by the heater 7c, and to supply water vapor into the treating chamber 3. The treating gas supply line (not shown here) is so configured that each of treating gases such as oxygen and dinitrogen monoxide is supplied from a pressure cylinder of the treating gas into the treating chamber 3.

In the treating apparatus 1 configured as above, a high-pressure water vapor atmosphere can be maintained inside the treating chamber 3, and a heat treatment in the high-pressure water vapor atmosphere (i.e., high-pressure water vapor anneal) can be applied to the substrates to be treated which are contained in the treating chamber 3. For example, when the high-pressure water vapor anneal is applied to a silicon oxide film formed on a substrate surface by a plasma CVD process or the like, unoxidized silicon remaining in silicon oxide can be oxidized, whereby an enhancement of the denseness of an oxide film and a reduction of fixed electric charges in the film can be contrived, so that an enhancement of the film quality of the oxide film can be contrived. On the other hand, the concentration of Si—OH bonds in the oxide film is increased by the water vapor anneal. Incidentally, the Si—OH bond concentration tends to be higher as the water vapor anneal temperature is lower.

### First Embodiment

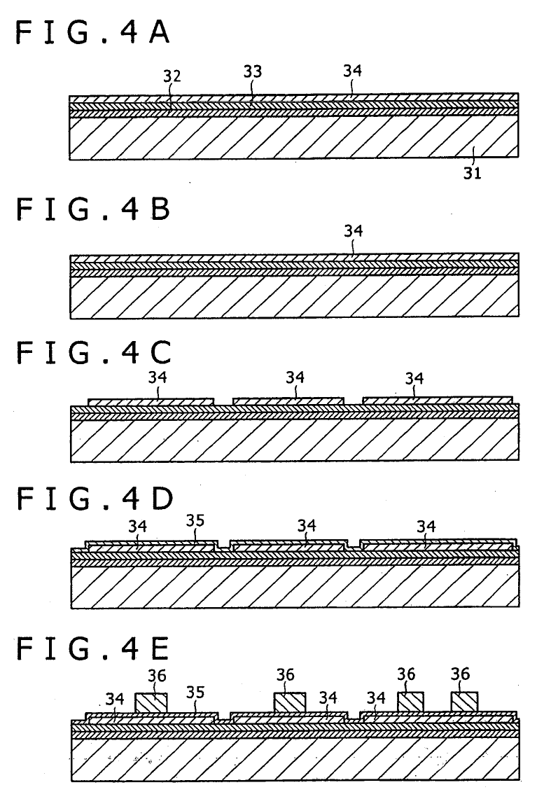

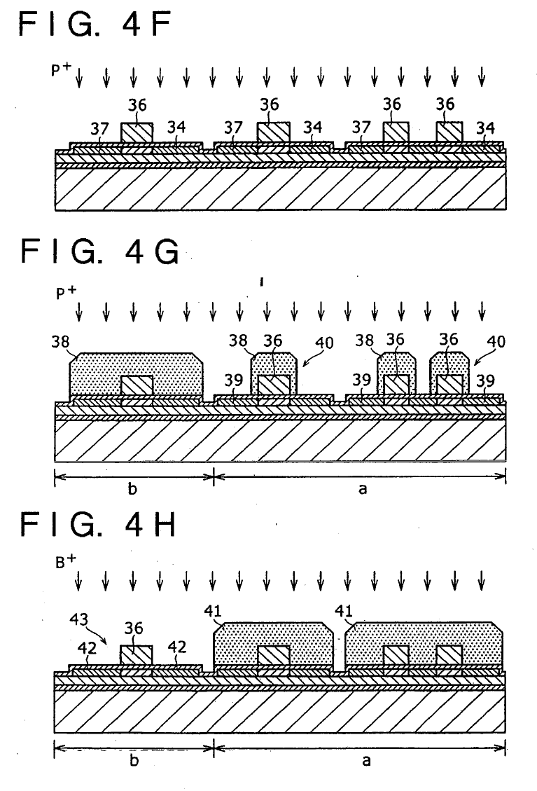

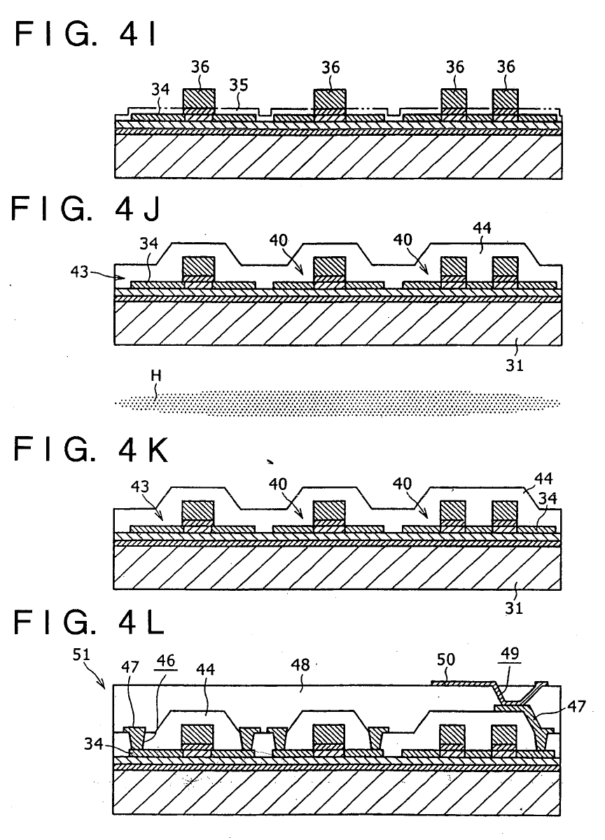

The sectional step views in FIGS. 4A to 4L are views for illustrating the method of manufacturing a thin film semiconductor device according to first embodiment. Here, a method of manufacturing a display drive panel (thin film semiconductor device) having top gate type TFTs as thin film transistors will be described using these figures.

First, as shown in FIG. 4A, an insulating substrate 31 is prepared. As the substrate 31, there can be used, for example, AN635 or AN100 produced by Asahi Glass Co., Ltd., or Code1737 or Eagle2000 produced by Corning Incorporated, or the like.

By use of a film forming method such as plasma CVD process and LPCVD process, a silicon nitride (SiNx) film 32 as a buffer layer is formed on the substrate 31, and a silicon oxide (SiOx) film 33 is formed in a film thickness of about 50 to 400 nm. In the case where the silicon nitride film 32 and the silicon oxide film 33 are formed by the plasma CVD process, first, the silicon nitride film 32 is formed by using an inorganic silane gas (SiH₄, Si₂H₆ or the like) and ammonia gas (NH₃) are used as film forming gases. The silicon oxide film 33 is formed by using the inorganic silane gas and oxygen (O₂) or dinitrogen monoxide (N₂O) as film forming gases. During the film formation, the substrate temperature is maintained at about 450° C.

After the above, a semiconductor thin film 34 composed of silicon or germanium or a laminate thereof is formed on the silicon oxide film 33 by plasma CVD process, reactive thermal CVD process, vacuum CVD process, or normal pressure CVD process. Here, the semiconductor thin film 34 has a film thickness of 10 to 100 nm, preferably 40 nm.

Thereafter, if necessary, dehydrogenation anneal for removing hydrogen remaining in the semiconductor thin film 34 is conducted.

Next, as shown in FIG. 4B, if necessary, a step for promoting crystallization of the semiconductor thin film 34 is conducted. In this case, irradiation with energy such as pulse excimer laser, Xe (xenon) ark lamp, high-pressure gas blow or the like. By this, faults in the polycrystal constituting the semiconductor thin film 34 are removed, crystal grain size is enlarged by melting and recrystallization or the like method, or only crystal faults are removed without melting, and crystallization of the material constituting the semiconductor thin film 34 is promoted. In this case, for example, a line beam laser of XeCl (xenon chloride) with a wavelength of 308 nm is used as the excimer laser, and the pulse repetition frequency is set at about 200 Hz. Besides, the laser irradiation energy is set in the range of 200 to 400 mJ/cm².

Next, as shown in FIG. 4C, the semiconductor thin film 34 is subjected to pattern etching, for separation into islands.

Thereafter, as shown in FIG. 4D, a gate insulation film 35 formed of silicon oxide is formed in a film thickness of about 100 nm by a plasma CVD process. Thereafter, if necessary, B+ ions are injected into the semiconductor thin film 34 in a dose of about 0.1E12 to 4E12/cm², for the purpose of controlling the Vth of the thin film transistors to be formed here. In this case, the ion beam acceleration voltage is set at about 20 to 200 keV.

Next, as shown in FIG. 4E, gate electrodes 36 are formed on the patterned semiconductor thin film 34, with the gate insulation film 35 therebetween. In this case, first, a film of aluminum (Al), titanium (Ti), molybdenum (Mo), tungsten (W), tantalum (Ta), polysilicon doped with impurity (doped poly-Si) or an alloy of them is formed in a film thickness of 200 to 800 nm on the gate insulation film 35, and is subjected to patterning, to form the gate electrodes 36.

Thereafter, as shown in FIG. 4F, impurity introduction for forming an LDD diffusion layer 37 of n-type MOS transistors in the semiconductor thin film 34 is conducted by an ion injection process using the gate electrodes 36 as a mask. In this case, by using P⁺ ions, for example, mass separation ion injection is conducted under the conditions of an injection dose of 6E12 to 5E13/cm² and an acceleration voltage of about 20 to 200 keV.

Next, as shown in FIG. 4G, a resist pattern 38 covering side walls of the gate electrodes 36 in an n-channel region a and covering a p-channel region b is formed, and impurity introduction for forming source/drain regions 39 of the n-channel thin film transistors is conducted by ion injection using the resist pattern 38 as a mask. In this case, by using P.sup.+ ions, for example, mass separation or non-mass-separation type ion shower doping is conducted under the conditions of an injection dose of 1E14 to 3E15/cm² and an acceleration voltage of about 20 to 200 keV. By this, n-channel thin film transistors (nTFT) 40 are formed. After the ion injection, the resist pattern 38 is stripped.

Further, as shown in FIG. 4H, a resist pattern 41 covering the n-channel region a is formed, and impurity introduction for forming source/drain regions 42 of p-channel thin film transistors is conducted by an ion injection process using the resist pattern 41 and the gate electrodes 36 in the p-channel region b as a mask. In this case, by using B+ ions, for example, injection is conducted under the conditions of an injection dose of 1E15 to 3E15/cm² and an acceleration voltage of about 10 to 100 keV, to form the p-channel thin film transistors (pTFT) 43. After the ion injection, the resist pattern 41 is stripped.

After the above, as shown in FIG. 4I, the gate insulation film 35 is removed by etching with the gate electrodes 36 as a mask. By this, the gate insulation film 35 is patterned into the shape of lamination on the gate electrodes 36, and the portions of the gate insulation film 35 overlapping with the semiconductor thin film 34 in other areas are removed.

Next, as shown in FIG. 4J, a layer insulation film 44 containing no —H group in the film of at least the lowermost layer is formed on the substrate 31 so as to cover the nTFTs 40 and the pTFTs 43. Here, as an example of the layer insulation film 44 containing no —H group in the film, a layer insulation film 44 formed of silicon nitride is formed in a film thickness of 200 to 400 nm. Since silicon nitride is low in oxygen content, the —H group concentration in the film is extremely low. It should be noted, however, that the —H bond concentration in the film is less than 1×10²¹ cm⁻³ when the film contains no −H group.

Incidentally, the layer insulation film 44 may be a laminate film having a silicon oxide film further formed in a film thickness of 100 to 200 nm on the silicon nitride film. In such a laminate structure, the lowermost layer of the layer insulation film 44 is composed of the silicon nitride film containing no —H group in the film. It should be noted in this case that the formation of the silicon oxide film as the upper layer is preferably conducted by such a film forming method that hydroxyl groups will not be contained in the film. Here, the film forming method such that hydroxyl groups will not be contained in the film is, for example, an electron cyclotron resonance (ECR) CVD process or a magnetron sputtering process.

In addition, the layer insulation film 44 may be a layer of silicon oxynitride (SiNxOy). Silicon oxynitride can be obtained by use of plasma decomposition of a mixture of an inorganic silane gas (SiH₄, Si₂H₆ or the like) and dinitrogen monoxide supplied in a predetermined flow rate ratio, and the amount of —OH bonds in the film can be extremely low and in the above-mentioned range.

Incidentally, in the case where a silicon oxide film is formed as the layer insulation film 44, the amount of Si—OH bonds (—OH group concentration) in the silicon oxide film can be determined by the Fourier-transform infrared spectroscopy (FT-IR), for example; in this method, when the OH bond amount is below the detection limit, the film can be deemed as containing no Si—OH bond.

After the layer insulation film 44 with the lowermost layer containing no —OH group is formed, an activation annealing treatment is conducted by a method appropriately selected from laser anneal, lamp anneal, furnace anneal and the like, for activating the impurity introduced into the semiconductor thin film 34.

Next, as shown in FIG. 4K, an annealing treatment in a moisture atmosphere H, i.e., so-called water vapor anneal is conducted, whereby oxygen or hydrogen is linked to dangling bonds in the semiconductor thin film 34 constituting the nTFTs 40 and the pTFTs 43, and an increase in the denseness of the layer insulation film 44 is contrived. The treating conditions in this case are, for example, a temperature of 200 to 600° C., a pressure of from atmospheric pressure to 2 MPa, and a time of 1 to 2 hr, corresponding to the so-called “high-pressure water vapor anneal”. In addition, the anneal temperature is preferably 450° C. or below, since hydrogen is eliminated at a temperature exceeding 450° C., because the dissociation temperature of the hydrogen bond relative to silicon is in the vicinity of 450° C. Furthermore, the water vapor atmosphere in the high-pressure water vapor anneal may contain oxygen gas, nitrogen gas, inert gas, ozone gas, or dinitrogen monoxide gas.

Here, whether the layer insulation film 44 has been made denser can be confirmed from the fact that the half width of a peak appearing in the absorption spectrum in a specified wavelength region upon FT-IR is narrower than that for a film not subjected to the water vapor anneal. For example, in the case of silicon oxide, the FT-IR spectrum has an absorption peak in the vicinity of a wavelength of 1050 to 1090 cm⁻¹, and the denseness of the silicon oxide film can be judged by the magnitude of the peak half-width. Besides, in the case of a silicon oxide film, the film can be judged as a comparatively coarse film when the half-width of the absorption peak appearing in the vicinity of 1050 to 1090 cm⁻¹ is greater than 90 cm⁻¹, and the film can be judged as a dense film when the half-width is smaller than 80 cm⁻¹.

Next, as shown in FIG. 4L, the layer insulation film 44 is provided with contact holes 46 reaching the semiconductor thin film 34. Then, wiring electrodes 47 connected to the semiconductor thin film 34 via the contact holes 46 are formed. The formation of the wiring electrodes 47 is conducted by forming a film of a wiring electrode material such as Al—Si by sputtering, followed by patterning of the film.

Thereafter, a flattening insulation film 48 formed of an acrylic organic resin, for example, is formed by coating in a film thickness of about 1 μm, and the flattening insulation film 48 is provided with contact holes 49 reaching the wiring electrodes 47. Then, pixel electrodes 50 connected to the wiring electrodes 47 via the contact holes 49 are formed on the flattening insulation film 48. The pixel electrodes 50 are formed, for example, by sputtering a film of ITO (Indium Tin Oxide) as a transparent conductive material, followed by patterning. Besides, where the pixel electrodes 50 are formed of ITO, the pixel electrodes 50 are annealed in a nitrogen atmosphere at a temperature of about 220° C. for 30 min. By this, the thin film semiconductor device 51 to be a display drive panel is completed.

In the thin film semiconductor device 51 produced as above, as has been described above using FIG. 4J, the layer insulation film 44 containing no —OH group in the lowermost layer is formed in the state of covering the TFTs 40 and 43. Therefore, at the time of the high-pressure water vapor anneal conducted in the step described above referring to FIG. 4K, oxygen is bound to the dangling bonds in the semiconductor thin film 34 constituting the TFTs 40 and 43 and the dangling bonds are thereby terminated with oxygen (partly hydrogen), without any influence of the —OH groups in the layer insulation film 44 on the TFTs 40 and 43.

Particularly, since the high-pressure water vapor anneal can be conducted without any influence of the —OH groups in the layer insulation film 44 on the TFTs 40 and 43 as above-mentioned, an abnormal shift of the threshold (Vth) of the nTFT 40 is obviated, and it is possible to obtain the TFTs 40 and 43 with stable Vth irrespectively of the conduction type. In addition, since the gate insulation film 35 is patterned into the shape laminated on the gate electrodes 36 and the portions of the gate insulation film 35 overlapping with the semiconductor thin film 34 in other areas are removed as has been described above referring to FIG. 4I, the influence of the —OH groups contained in the gate insulation film 35 on the semiconductor thin film 34 of the TFTs 40 and 43 can be minimized, and it is possible to obtain TFTs 40 and 43 with further stable Vth.

In addition, since the high-pressure water vapor anneal is applied also to the layer insulation film 44 as above mentioned, an enhancement of the denseness of the layer insulation film 44 can be contrived. This ensures that the electrostatic endurance of the layer insulation film 44 can be enhanced, and electrostatically caused defects can be prevented from being generated.

As a result of the foregoing, an enhancement of the reliability of the thin film semiconductor device 51 can be contrived. In addition, with the thin film semiconductor device 51 used as a display drive panel, dispersion of TFT device characteristics in the substrate 31 is reduced, which can greatly contribute to realization of a system display liquid crystal panel, organic EL panel or the like in which high-function circuits are integrated on a display panel.

Besides, since the water vapor anneal is conducted in the method of terminating the dangling bonds in the semiconductor thin film 34 with oxygen or hydrogen, a high through-put can be achieved.

### Second Embodiment

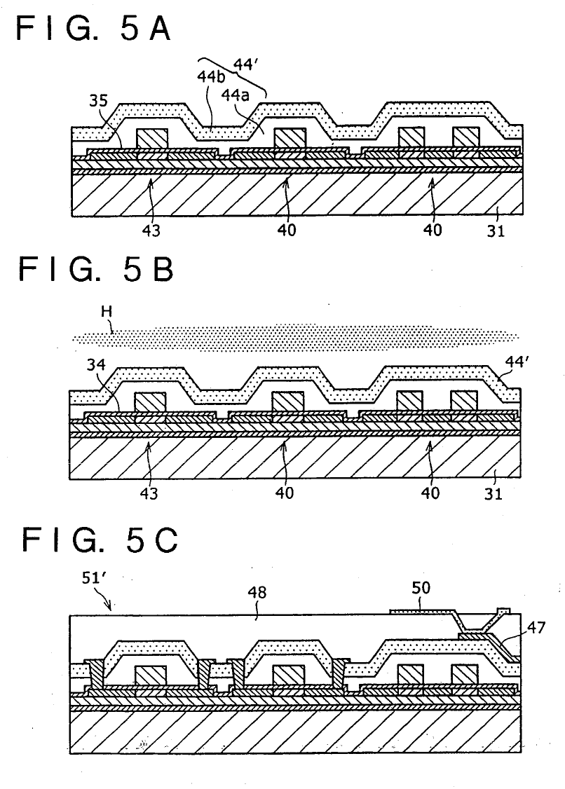

Now, the method of manufacturing a semiconductor thin film according to a second embodiment will be described below referring to the sectional step diagrams shown in FIGS. 5A to 5C.

First, following the same procedure as described using FIGS. 4A to 4H in the first embodiment above, the steps from the formation of nTFTs 40 and pTFTs 43 on a substrate 31 to the stripping of a resist pattern 41 are carried out.

Incidentally, in the step shown in FIG. 4D, the formation of a gate insulation film 35 is preferably carried out by the film forming method wherein a film containing no hydroxyl group is formed. Here, the film forming method wherein a film containing no hydroxyl group is the above-mentioned electron cyclotron resonance (ECR) plasma CVD process or magnetron sputtering process.

Next, as shown in FIG. 5A, without removing the gate insulation film 35, a silicon nitride film 44a is formed in a film thickness of 200 to 400 nm on the substrate 31 so as to cover the nTFTs 40 and the pTFTs 43, and a silicon oxide film 44b is formed in a film thickness of 100 to 200 nm on the silicon nitride film 44a. By this, a layer insulation film 44′ having a laminate structure is obtained. In this case, the formation of the silicon oxide film 44b is preferably conducted by the above-mentioned ECR-CVD process or magnetron sputtering process, but may be conducted by a plasma-CVD process.

Thereafter, an activation annealing treatment is conducted by a method appropriately selected from laser anneal, lamp anneal, furnace anneal and the like, for activating the impurity introduced into the semiconductor thin film 34.

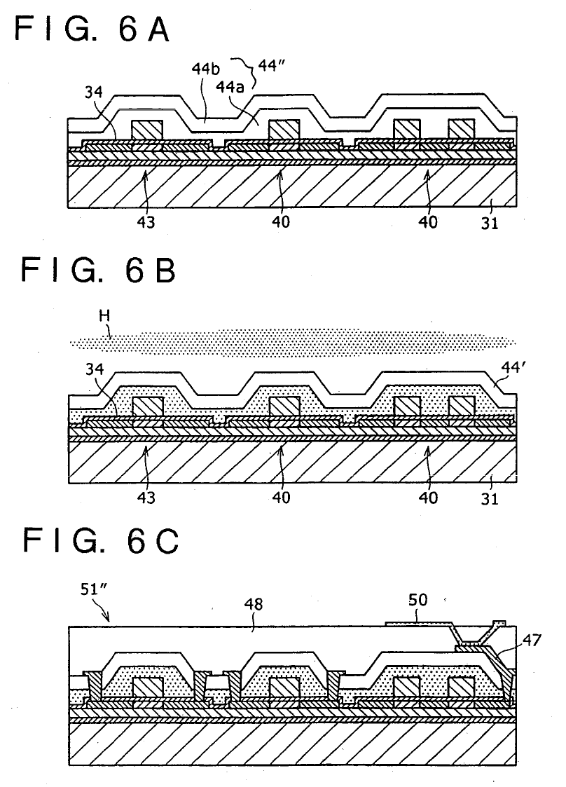

Thereafter, the step shown in 5B is carried out by the same “high-pressure water vapor anneal” as described above using FIG. 6C in the first embodiment, whereby oxygen or hydrogen is bound to the dangling bonds in the semiconductor thin film 34 constituting the nTFTs 40 and the pTFTs 43, and an enhancement of the denseness of the layer insulation film 44′ is contrived.

Next, the step shown in FIG. 5C is conducted in the same manner as described above using FIG. 4L in the first embodiment, whereby wiring electrodes 47, a flattening insulation film 48 and pixel electrodes 50 are formed, to complete a display drive panel (thin film semiconductor device) 51′.

Even by such a manufacturing method, the layer insulation film 44′ containing no —OH group in the lowermost layer film formed of silicon nitride is formed in the state of covering the TFTs 40 and 43, and, thereafter, high-pressure water vapor anneal is conducted, as described referring to FIGS. 5A and 5B, in the same manner as in the manufacturing method according to the first embodiment above. Therefore, like in the first embodiment, it is possible to obtain TFTs 40 and 43 with stable Vth irrespectively of conduction type, to contrive an enhancement of the denseness of the layer insulation film 44′, to enhance the electrostatic endurance of the layer insulation film 44′, to prevent electrostatically caused defects from being generated, and to contrive an enhancement of the reliability of the thin film semiconductor device 51′.

Particularly, since the formation of the silicon oxide film constituting the gate insulation film 35 and the formation of the silicon oxide film constituting the upper layer of the layer insulation film 44′ are conducted by use of the ECR-CVD process or magnetron sputtering process, these films contain few —OH groups, so that the shift of the threshold (Vth) of the nTFTs 40 can be suppressed further securely.

### Third Embodiment

Now, the method of manufacturing a semiconductor thin film according to a third embodiment will be described below referring to sectional step diagrams shown in FIGS. 6A to 6C. The manufacturing method according to the third embodiment shown in these figures differs from the manufacturing method according to the second embodiment described referring to FIGS. 5A to 5C, in the configuration of a layer insulation film 44″.

Specifically, after the formation of nTFTs 40 and pTFTs 43 in the same manner as in the second embodiment, as shown in FIG. 6A, the layer insulation film 44″ containing no —OH group in at least the lowermost layer film is formed on a substrate 31 so as to cover the nTFTs 40 and the pTFTs 43, without removing a gate insulation film 35. In this case, in an order reverse to that in the second embodiment, a silicon oxide film 44b is first formed and thereafter a silicon nitride film 44a is formed. By this, the layer insulation film 44″ having a laminate structure is obtained. It should be noted here that the formation of the silicon oxide film 44b is conducted by a film forming method such that the film will contain no —OH group, such as the ECR-CVD process or magnetron sputtering process.

Thereafter, an activation annealing treatment is conducted by a method appropriately selected from laser anneal, lamp anneal, furnace anneal and the like, for activating the impurity introduced into the semiconductor thin film 34.

Thereafter, the step shown in FIG. 6B is conducted by the same “high-pressure water vapor anneal” as that described using FIG. 6C in the first embodiment above, whereby oxygen or hydrogen is bound to the dangling bonds in the semiconductor thin film 34 constituting the nTFTs 40 and the pTFTs 43, and an enhancement of the denseness of the layer insulation film 44′ is contrived.

Next, the step shown in FIG. 6C is conducted in the same manner as has been described above using FIG. 4L in the first embodiment, whereby wiring electrodes 47, a flattening insulation film 48 and pixel electrodes 50 are formed, to complete a display drive panel (thin film semiconductor device) 51″.

In such a manufacturing method, as has been described above using FIGS. 6A and 6C, the layer insulation film 44′ composed of the silicon oxide film 44b containing no —OH group in the lowermost layer is formed in the state of covering the TFTs 40 and 43, and thereafter high-pressure water vapor anneal is conducted. Therefore, like in the first embodiment and the second embodiment, it is possible to obtain TFTs 40 and 43 with stable Vth irrespectively of conduction type, to contrive an enhancement of the denseness of the layer insulation film 44′, to enhance the electrostatic endurance of the layer insulation film 44″, to prevent electrostatically caused defects from being generated, and to contrive an enhancement of the reliability of the thin film semiconductor device 51″.

### Fourth Embodiment

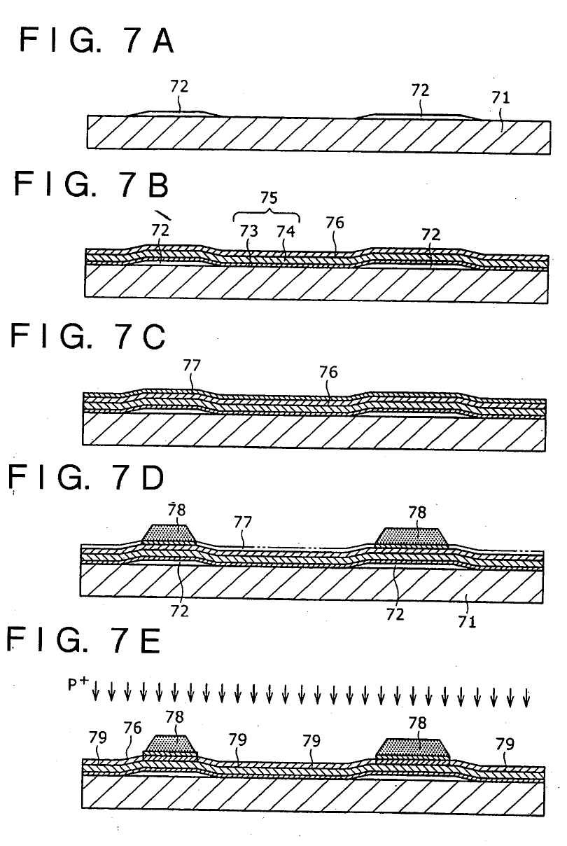

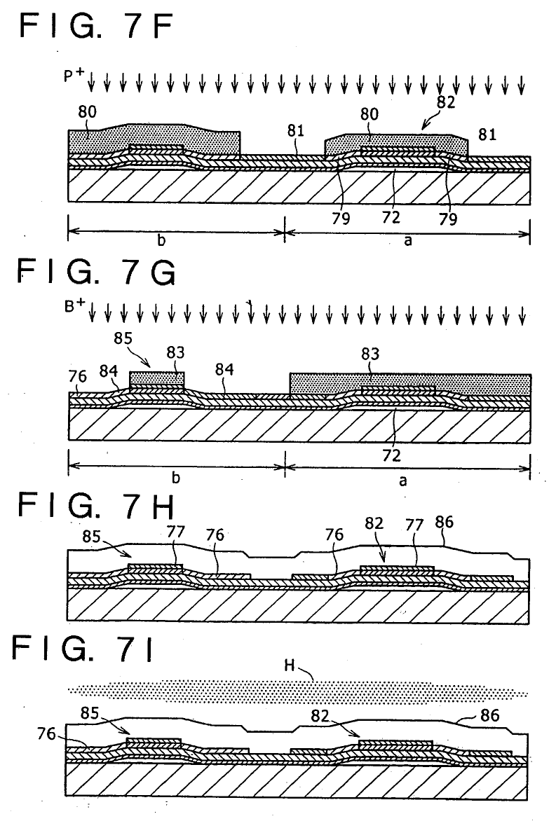

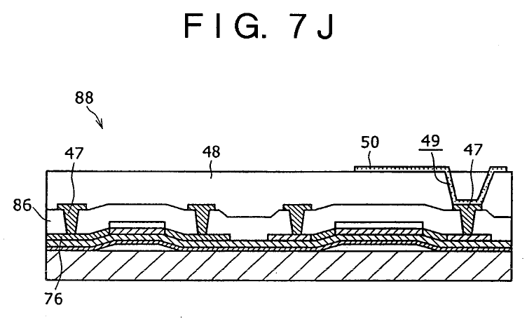

Now, the method of manufacturing a semiconductor thin film according to a fourth embodiment will be described below referring to sectional step diagrams shown in FIGS. 7A to 7I. Here, the method of manufacturing bottom gate type TFTs as thin film transistors will be described referring to these figures, and, further, the method of manufacturing a display drive panel (thin film semiconductor device) using this will be described.

First, as shown in FIG. 7A, gate electrodes 72 are formed on an insulating substrate 71 which is the same as that in the first embodiment. In this case, first, a film of tantalum (Ta), molybdenum (Mo), tungsten (W), chromium (Cr), copper (Cu), an alloy thereof or the like is formed in a film thickness of 20 to 250 nm on the substrate 71, and the film is patterned to form the gate electrodes 72.

Next, as shown in FIG. 7B, by plasma CVD process, normal pressure CVD process, or vacuum CVD process, a silicon nitride film 73 is formed in a film thickness of 30 to 350 nm on the substrate 71 in the state of covering the gate electrodes 72, and subsequently a silicon oxide film 74 is formed in a film thickness of 50 to 200 nm, to obtain a gate insulation film 75. Thereafter, the same semiconductor thin film 76 as in the first embodiment is formed on the gate insulation film 75. These film forming steps are continuously conducted in the same chamber.

Next, if necessary, following to the formation of the semiconductor thin film 76, rapid temperature elevation by irradiation with energy E of pulse excimer laser, Xe arc lamp or the like or by blowing a high-temperature (N₂) gas is applied to the semiconductor thin film 76, thereby promoting crystallization of the semiconductor thin film 76. This step is conducted in the same manner as described above referring to FIG. 4B in the first embodiment.

Thereafter, as shown in FIG. 7C, a cap insulation film 77 formed of silicon oxide is formed in a film thickness of 100 to 200 nm by a plasma CVD process. Then, if necessary, B⁺ ions are injected into the semiconductor thin film 76 in a dose of about 0.1E12 to 4E12/cm², for the purpose of controlling the Vth of the TFT. In this case, the ion beam acceleration voltage is set in the range of about 10 to 100 keV.

Next, as shown in FIG. 7D, by back exposure from the side of the substrate 71, a resist pattern 78 is formed on the cap insulation film 77 using the gate electrodes 72 as a mask. Then, etching is conducted using the resist pattern 78 as a mask, whereby the cap insulation film 77 in other areas than the gate electrodes 72 is removed, leaving the cap insulation film 77 on the gate electrodes 72.

Next, as shown in FIG. 7E, by an ion injection process using the resist pattern 78 as a mask, impurity introduction for forming an LDD diffusion layer 79 of n-channel thin film transistors (nTFT) in the semiconductor thin film 76 is conducted. In this case, for example, P.sup.+ ions are used, and mass separation ion injection is conducted under the conditions of an injection dose of 4E12 to 5E13/cm² and an acceleration voltage of about 10 to 100 keV.

Thereafter, as shown in FIG. 7F, a resist pattern 80 covering the gate electrodes 72 and the LDD diffusion layer 79 in n-channel regions a and the whole part of p-channel regions b is formed, and by an ion injection process using the resist pattern 80 as a mask, impurity introduction for forming source/drain regions 81 of n-channel thin film transistors (nTFT) is conducted. In this case, for example, P⁺ ions are used, and mass separation or non-mass-separation type ion shower doping is conducted under the conditions of an injection dose of 1E14 to 1E15/cm² and an acceleration voltage of about 10 to 100 keV, whereby nTFTs 82 are formed. After the ion injection, the resist pattern 80 is stripped.

Next, as shown in FIG. 7G, a resist pattern 83 covering the whole part of the n-channel regions a and the gate electrodes 72 in the p-channel regions b is formed, and by an ion injection process using the resist pattern 83 as a mask, impurity introduction for forming source/drain regions 84 of p-channel thin film transistors (pTFT) 85 is conducted. In this case, for example, H₂-diluted B₂H₆ gas is used, and B⁺ ions ions are injected under the conditions of an injection dose of 1E15 to 3E15/cm² and an acceleration voltage of about 10 to 100 keV, to form p-channel TFTs 85. After the ion injection, the resist pattern 83 is stripped.

Next, an activation annealing treatment for the impurity introduced into the semiconductor thin film 76 is conducted. The activation annealing treatment is carried out by a method appropriately selected from laser anneal, lamp anneal, furnace anneal and the like.

Thereafter, as shown in FIG. 7H, the semiconductor thin film 76 is patterned, for separation into islands, to thereby isolate the nTFTs 82 and the pTFTs 85 from each other. Next, a layer insulation film 86 containing no —OH group in at least the lowermost layer film is formed in the state of covering the cap insulation film 77, the nTFTs 82 and the pTFTs 85. Here, as an example of the layer insulation film 86 containing no —OH group in the film, a layer insulation film 86 formed of silicon nitride is formed in a film thickness of 100 to 400 nm. Incidentally, the layer insulation film 86 may be the same as the layer insulation film 86 described above using FIG. 4J in the first embodiment.

Next, the step shown in FIG. 7I is conducted by the same “high-pressure water vapor anneal” as described above referring to FIG. 4K in the first embodiment, whereby oxygen or hydrogen is bound to the dangling bonds in the semiconductor thin film 76 constituting the nTFTs 82 and the pTFTs 85, and an enhancement of the denseness of the layer insulation film 86 is contrived.

After the above, the same steps as described above using FIG. 4L in the first embodiment are carried out. Specifically, as shown in FIG. 7J, the layer insulation film 86 is provided with contact holes 87 reaching the semiconductor thin film 76. Then, wiring electrodes 47 connected to the semiconductor thin film 76 via the contact holes 87 are formed. Thereafter, a flattening insulation film 48 is formed by coating, and the flattening insulation film 48 is provided with contact holes 49 reaching the wiring electrodes 47. Then, pixel electrodes 50 connected to the wiring electrodes 47 via the contact holes 49 are formed on the flattening insulation film 48, to complete a thin film semiconductor device 88 to be a display drive panel.

Even in such a manufacturing method, like in the manufacturing method according to the first embodiment described above, as has been described using FIGS. 7H and 7I, the layer insulation film 86 formed of silicon nitride and containing no —OH group in the film is formed in the state of covering the TFTs 82 and 85, and thereafter the high-pressure water vapor anneal is conducted. Therefore, like in the first embodiment, it is possible to obtain TFTs 82 and 85 with stable Vth irrespectively of conduction type, to contrive an enhancement of the denseness of the layer insulation film 86, to enhance the electrostatic endurance of the layer insulation film 86, to prevent electrostatically caused defects from being generated, and to contrive an enhancement of the reliability of the thin film semiconductor device 88.

### EXAMPLES

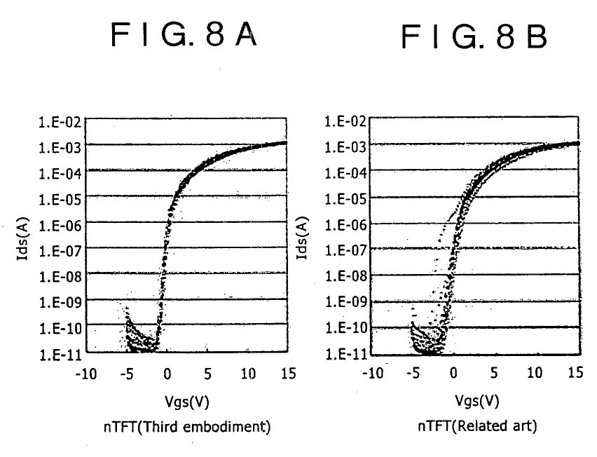

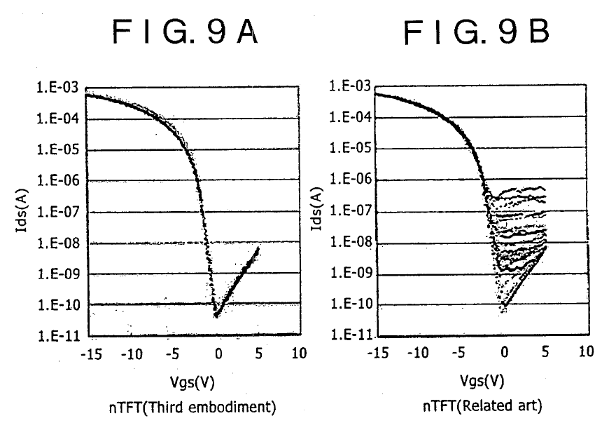

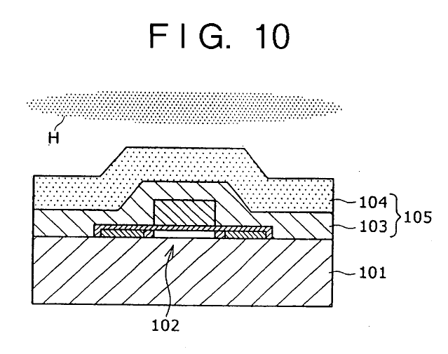

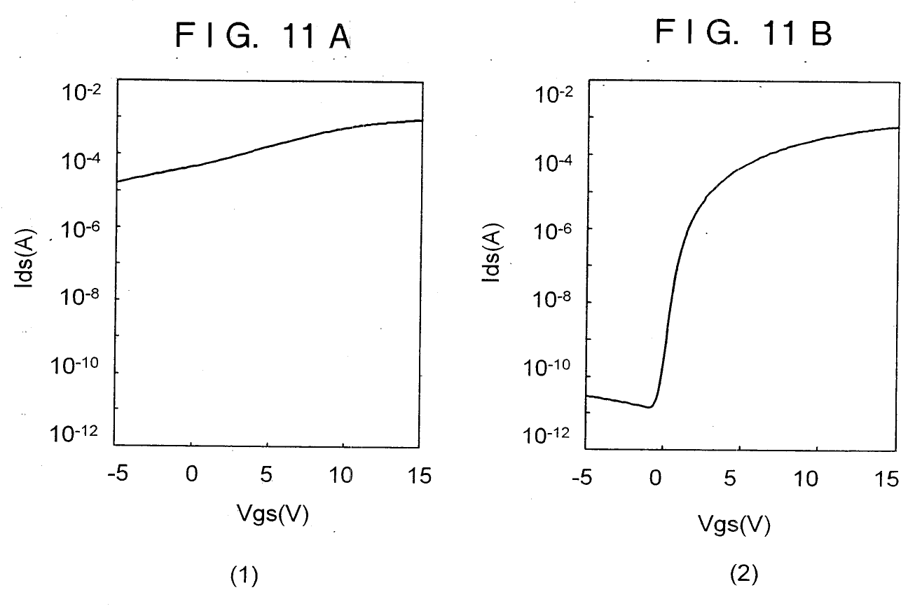

The results of measurement of characteristics of 28 independent TFTs formed in a matrix pattern on a glass substrate are shown in FIGS. 8A to 9B. FIGS. 8A and 9A show the transfer characteristic of a thin film transistor manufactured by the method according to the third embodiment described above. FIGS. 8B and 9B show the transfer characteristic of a thin film transistor manufactured through hydrogenation by anneal in a nitrogen atmosphere according to the related art, for comparison. Incidentally, FIGS. 8A and 8B show the transfer characteristics of nTFT, whereas FIGS. 9A and 9B show the transfer characteristics of pTFT. Besides, the anneal in the nitrogen atmosphere according to the related art was conducted with the same timing as the high-pressure water vapor anneal in the third embodiment.

As is clear from FIG. 8B, in the case of the nTFT obtained through hydrogenation by anneal in the nitrogen atmosphere according to the related art, the layer insulation film undergoes electrostatic damages due to the sputtering step, and the electrostatic damages serve as in-film electric charges, resulting in a “protuberance”-like scattered characteristic (part A in the figure) in a sub-threshold region in the case of the n-channel. Besides, as is clear from FIG. 9B, in the case of the pTFT obtained through hydrogenation by anneal in the nitrogen atmosphere according to the related art, an increase in leak current due to the in-film electric charges appears. In order to suppress such scattering of characteristic, in the past, it would be necessary to conduct a heat annealing step at about 200° C. after the sputtering step for the wiring electrodes, so as to reduce the sputter-induced damages. However, even upon such a heat annealing, some of the damages would be left instead of being removed, thereby causing the scattering of characteristic in the past.

In contrast, as is clear from FIGS. 8A and 9A, in the cases of nTFT and pTFT obtained by the manufacturing method according to the third embodiment of the present invention, the high-pressure water vapor anneal conducted after the formation of the layer insulation film promises an enhancement of the denseness of the layer insulation film. It is seen that, by this effect, there is few damages arising from the high-pressure sputtering step, and the scattering of characteristic is suppressed to an extremely low level.

In addition, as shown in FIG. 8A, in the method according to the third embodiment, it is confirmed that, even in the case where the water vapor anneal is conducted, the shift of the threshold (Vth) of nTFT is restrained. Besides, in comparison with the related art example shown in FIG. 8B, it is confirmed that the scattering itself of the threshold (Vth) is suppressed to a low level.

It should be understood by those skilled in the art that various modifications, combinations, sub-combinations and alterations may occur depending on design requirements and other factors insofar as they are within the scope of the appended claims or the equivalents thereof.

What is claimed is:

1. A method of manufacturing a thin film semiconductor device, comprising:
a first step of forming a thin film transistor on a substrate;
a second step of forming a layer insulation film on said substrate the layer insulatin film containing no hydroxyl group in at least a film constituting a lowermost layer, in the state of covering said thin film transistor; and
a third step of linking oxygen or hydrogen to dangling bonds in the semiconductor thin film constituting said thin film transistor by a heat treatment in a moisture atmosphere after the formation of said layer insulation film.

2. A method of manufacturing a thin film semiconductor device as set forth in claim 1, wherein said layer insulation film including silicon nitride is formed in said second step.

3. A method of manufacturing a thin film semiconductor device as set forth in claim 1, wherein said layer insulation film having a laminate structure of a silicon nitride film and a silicon oxide film is formed in said second step.

4. A method of manufacturing a thin film semiconductor device as set forth in claim 1, wherein said heat treatment in said third step is carried out in a pressurized atmosphere.

5. A method of manufacturing a thin film semiconductor device as set forth in claim 1, wherein an insulation film containing no hydroxyl group is formed as a gate insulation film of said thin film transistor, in said first step.

6. A method of manufacturing a thin film semiconductor device as set forth in claim 1, wherein a gate insulation film in said thin film transistor is patterned into a shape for lamination on a gate electrode in said thin film transistor, in said first step.
